(19) United States
(12) Patent Application Publication
(10) Pub. No.: US 2010/0070213 A1
(43) Pub. Date: Mar. 18, 2010

(54) Method for Monitoring the Electrical Energy Quality in an Electrical Energy Supply System, Power Quality Field Device and Power Quality System

(75) Inventor: Uwe Anklam, Kammerstein (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, München (DE)

(21) Appl. No.: 12/297,540

(22) PCT Filed: Apr. 18, 2006
(86) PCT No.: PCT/DE2006/000696

§ 371 Date: Oct. 17, 2008

(51) Int. Cl. G01R 21/06

(52) U.S. Cl. 702/60

(57) ABSTRACT

To carry out monitoring of the electrical energy quality of an electrical energy supply system using an electrical power quality field device with comparatively little complexity, a method performs the steps of: detecting a first measured value of a first power quality characteristic by a measuring device of a power quality field device arranged at a measurement point of the electrical energy supply system at a first measurement time; detecting a second measured value of the first power quality characteristic by the measuring device at a second measurement time, which directly follows the first measurement time; comparing the first and second measured values with at least one predetermined threshold value; and generating an event signal, which indicates a violation of the threshold value, precisely when one of the two measured values is above and one of the two measured values is below the threshold value.

Nowadays, electrical power supply systems represent highly complex networks for distribution of electrical power, which often have a large number of power feeds and outgoers. In addition to supply reliability, that is to say ensuring that a sufficient amount of electrical power is available for every power consumer at all times, the quality of the electrical power that is supplied (referred to in the following text as the “electrical power quality” or “power quality”) also plays a critical role. The electrical power quality in the power supply system can be defined, for example, using so-called power quality characteristic variables such as the frequency, voltage and voltage harmonics or current harmonics, distortion factors, flicker, voltage imbalances and powers. Highly sensitive electrical devices nowadays demand an electrical power supply in the form of a sinusoidal wave which is as pure as possible and is at a standard frequency and has a standard amplitude. Standards such as EN 50160 or IEC 61000 therefore specify upper and lower limit values within which these power quality characteristic variables of a power supply system must lie.

To allow statements to be made about the electrical power quality, power quality field devices which record measured values of the respective power quality characteristic variables are provided at various measurement points in the electrical power supply system. The recorded measured values can normally be stored, for archiving, in power quality field devices. The stored measured values are transmitted at regular intervals to other data processing facilities, for example to central evaluation computers, which carry out an evaluation, in order to evaluate the measured values to determine whether limit values have been exceeded at specific times. Time-dependent profiles of the power quality characteristic variables can therefore be produced in the central evaluation computer, and compliance with the limit values can be checked and verified.

Since the data memory modules incorporated in the power quality field devices cannot be chosen to be indefinitely large, for cost reasons, the stored measured values must be transmitted to the central evaluation computer relatively frequently. If the stored measured values are not transmitted at the right time, then either no more new measured values can be stored, because the data memory is completely full, or old measured values will be overwritten by more recent ones (so-called “ring memory operation”). In order to increase the time intervals between two transmission processes in this case, it would therefore be necessary to provide a correspondingly larger data memory in the power quality field device.

The invention is based on the object of specifying a method for monitoring the electrical power quality in an electrical power supply system, a power quality device and a power quality system, thus allowing the electrical power quality to be monitored with comparatively little effort.

With regard to the method, this object is achieved by a method for monitoring the electrical power quality in an electrical power supply system, in which the following steps are carried out:
detection of a first measured value of a first power quality characteristic variable by means of a measurement device of a power quality field device, which is arranged at a measurement point in the electrical power supply system, at a first measurement time;
detection of a second measured value of the first power quality characteristic variable by means of the measurement device of the power quality field device at a second measurement time, which directly follows the first measurement time;
comparison of the first and the second measured value with at least one predetermined threshold value, and
production of an event signal, which indicates infringement of the at least one threshold value, when and only when one of the two measured values is above the at least one threshold value and one of the two measured values is below the at least one threshold value.

The major advantage of the method according to the invention is that the power quality field device itself carries out a first assessment of the state of the electrical power quality of the electrical power supply system such that it is no longer necessary to store all the detected measured values in a data memory in the power quality field device for subsequent evaluation and, instead, an event signal is produced only if at least one of the threshold values, of which the power quality field device is aware, is or are infringed. This makes it possible to considerably reduce the required memory capacity and costs associated with it for the power quality field device.

One advantageous development of the method according to the invention provides that the event signal is used to control an optical signaling device of the power quality field device. This allows a threshold value infringement to be indicated directly on the power quality field device. In this case, by way of example, the indicating device may be a light-emitting diode, which indicates only the presence of a threshold value infringement, or a screen (for example an LCD) which indicates additional information relating to the threshold value that has been infringed.

A further advantageous embodiment of the method according to the invention provides that the event signal causes a control device for the power quality field device to produce a data message, with the data message including at least one data record which indicates the infringed threshold value. This generates an alarm message, so to speak, in the form of the data message which indicates information about the infringed threshold value to the operator of the electrical power supply system. In addition, further information, for example an identification (for example a serial number) of the power quality field device, can be included in the data message in order that the operator can clearly associate the threshold value infringement with one specific power quality field device and therefore with a specific measurement point in the electrical power supply system.

In this context, it is also considered to be advantageous for the data message to additionally include a data record which indicates the first and/or the second measurement time. This allows the threshold value infringement to be clearly associated with a time.

Furthermore, in this context, it is advantageous for the data message to additionally include information about whether the infringed threshold value has been infringed by overshooting it or undershooting it. This makes it possible, so to speak, to indicate a direction of the threshold value infringement.

Furthermore, in this context, provision may be made for the data message to additionally include the first and/or the second measured value. This allows an even more comprehensive evaluation of the threshold value infringement to be carried out since the extent by which the threshold value has been overshot or undershot can also be determined on the basis of the measured values.

In this context, it may also be advantageous to provide for the data message to be stored in a non-volatile data memory in the power quality field device and/or to be transmitted to a data processing facility which is superordinate to the power quality field device. This allows the operator to access the data message either directly on transmission of the data message by means of the superordinate data processing facility or, if the data message is stored in the power quality field device, by reading the non-volatile data memory. Even if the data message is stored in the power quality field device, this results in a considerable reduction in the amount of memory space required, in comparison to the storage of all the measured values.

A further advantageous embodiment of the method according to the invention provides that the event signal causes a control device for the power quality field device to store the first measured value and/or the second measured value in a non-volatile data memory in the power quality field device. In this case, therefore, only those two measured values between which a threshold value infringement has occurred are stored. This means that considerably fewer measured values are stored in the non-volatile data memory than in the case of continuous data storage, as a result of which its capacity is sufficient for a considerably longer measurement time period.

According to an advantageous development of the method according to the invention, provision is made, in addition to the measured values, for the first and/or the second measurement time to be also stored in the non-volatile data memory. This means that it is clearly possible to determine during the evaluation of the stored measured values the time at which a threshold value infringement occurred.

A further advantageous embodiment of the method according to the invention provides that the power quality field device (50) records a time clock of a device-internal timer and uses this time clock to determine the measurement time of the respective measured value. This allows a so-called time stamp to be allocated to each measured value, in a simple manner.

However, it is regarded as particularly advantageous if the power quality field device records an external time clock and determines the measurement time of the respective measured value on the basis of this external time clock. The privision of an external time clock, that is to say a time clock which is produced outside the field device (for example a GPS time signal), allows the measured values from a plurality of power quality field devices to be compared with one another even better, since each power quality field device is synchronized in time to the other power quality field devices. Each measured value is therefore associated with a measurement time which is determined exclusively by the external time clock and also has absolute validity in the other power quality field devices.

A further advantageous embodiment of the method according to the invention also provides that in addition to measured values of the first power quality characteristic variable, measured values of at least one further power quality characteristic variable are also detected, and a further event signal is produced when two measured values, with one following the other directly in time, of the at least one further power quality characteristic variable are located on different sides of at least one further threshold value. This allows a complete analysis of the relevant power quality characteristic variables to be carried out by a power quality field device.

Finally, it is also considered to be advantageous with regard to the method according to the invention for the event signal to cause the control device to additionally carry out further power quality functions of the power quality field device. In this case, for example, the event signal can be used to cause the power quality field device to record additional measured values over a defined time period, that is to say to produce a so-called fault plot, on the basis of which the measured value profiles of the power quality characteristic variables can be displayed accurately before and after the threshold value infringement. Such fault plots can either be stored in the non-volatile data memory in the power quality field device or can be transmitted to a superordinate data processing facility. In addition to the creation of fault plots, the event signal can also, for example, be used to trigger an increase in the sampling rate at which the measured values are recorded.

With regard to the power quality field device, the object mentioned above is achieved according to the invention by a power quality field device having a measurement device for detecting measured values, and a control device which is designed such that it compares the detected measured values with at least one predetermined threshold value and produces an event signal when, of two measured values which follow one another directly, one is above the at least one threshold value and one is below the at least one threshold value. This allows the state of the electrical power quality of the electrical power supply system to be assessed at this stage. Furthermore, the amount of data that is to be stored in the non-volatile data memory can be reduced considerably in comparison to continuous data storage since only an event signal is produced.

The power quality field device is advantageously provided with an indicating device (light-emitting diode, screen) which can be activated by the event signal.

One advantageous development of the power quality field device provides that the field device has a communication device which, when the event signal is present, sends a data message, which indicates the infringed threshold value, to a data processing facility which is superordinate to the power quality field device. The immediate transmission of the data message makes it possible to save memory space in the power quality field device.

Furthermore, it is advantageously possible to provide that the power quality field device has a non-volatile data memory in which, when the event signal is present, at least one data record which indicates the infringed threshold value is stored by means of the control device. This development as well allows memory capacity to be saved in the power quality field device in comparison to continuous data storage.

It is advantageously possible to provide that the control device is also designed to carry out functions for protection of components of an electrical power supply system. This relates to a combined power quality field device and protective device. Overall, this allows a smaller number of field devices to be provided for an electrical power supply system than when using separate power quality field devices and protective devices. In addition, in this case, both the power quality functions and the protective functions of the combined field device can access the same measurement inputs, as a result of which a small number of measurement transducers is required.

A further advantageous embodiment of the field device according to the invention provides that the field device has a device-internal timer which is designed to produce a time clock, and the control device is designed to determine the respective measurement time of the individual detected measured values on the basis of this time clock. This allows a time stamp to be allocated to each measured value in a simple manner.

One particularly advantageous embodiment of the power quality field device according to the invention provides, however, that the field device has a receiving device which is designed to receive an external time clock, and the control device is designed to determine the respective measurement time of the individual detected measured values on the basis of the received external time clock. This allows the power quality field device to associate measurement times with the measured values, which measurement times are dependent only on the external time clock and are therefore also valid in other devices which receive the same time clock. In this context, it is advantageously possible to provide for the receiving device to be a GPS receiver.

A plurality of such power quality field devices together with a central data processing facility to which they are connected via a data communication network may form a power quality system.

The invention will be explained in the following text with reference to exemplary embodiments. In this case, in the figures, in detail:

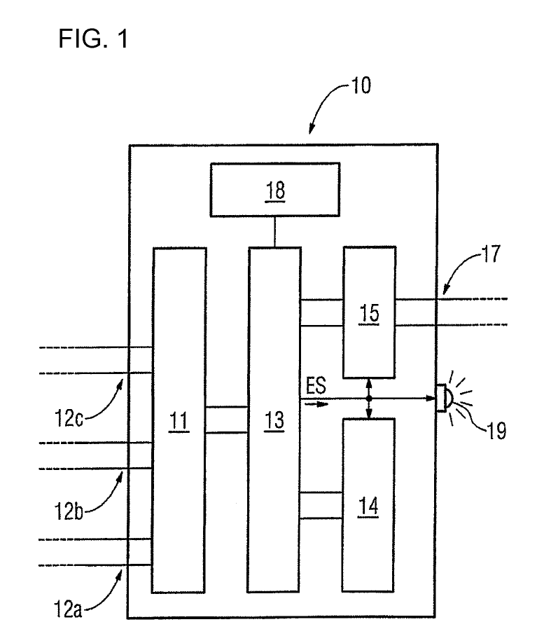

FIG. 1 shows a first exemplary embodiment of an electrical power quality field device, in the form of a schematic block diagram illustration,

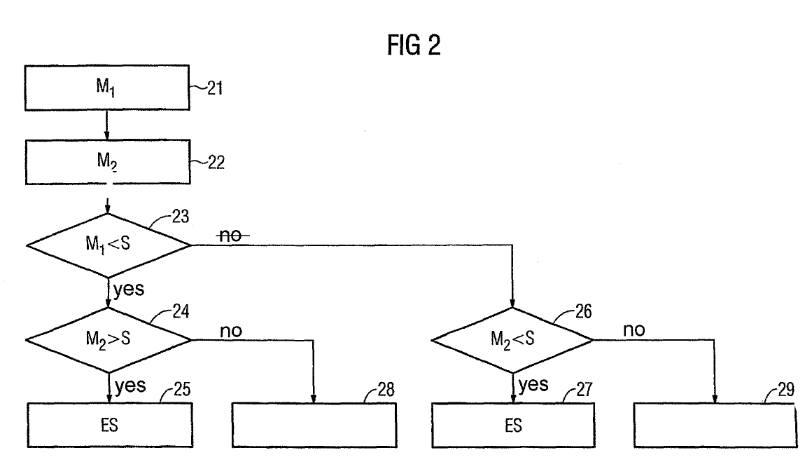

FIG. 2 shows a method flowchart in order to explain a method for monitoring the electrical power quality in an electrical power supply system,

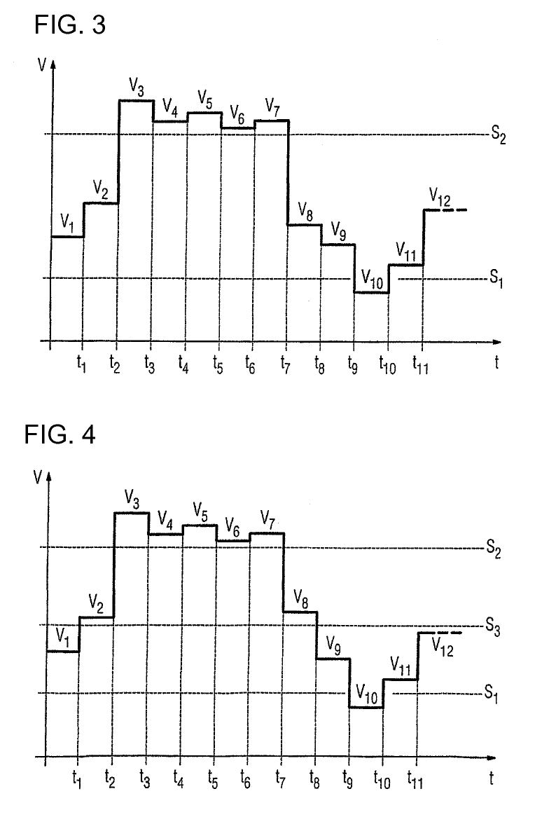

FIG. 3 shows a first graph with an example of a profile of measured values,

FIG. 4 shows a second graph with a second example of a profile of measured values,

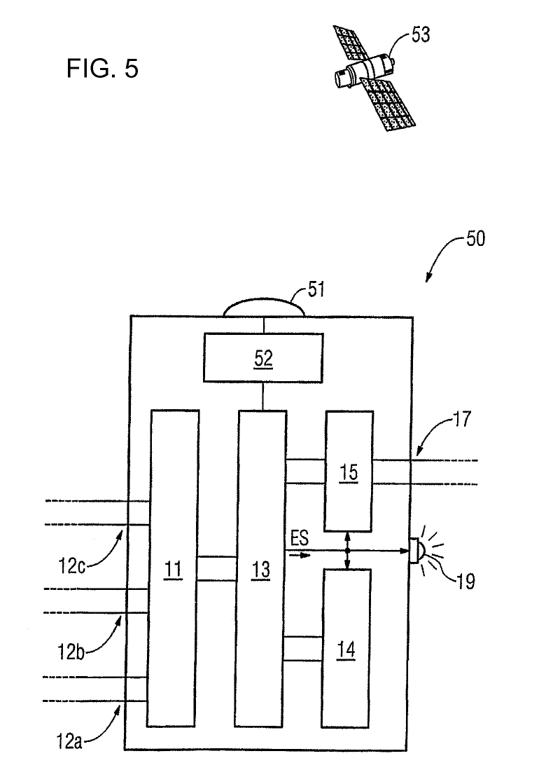

FIG. 5 shows a second exemplary embodiment of an electrical power quality field device, and

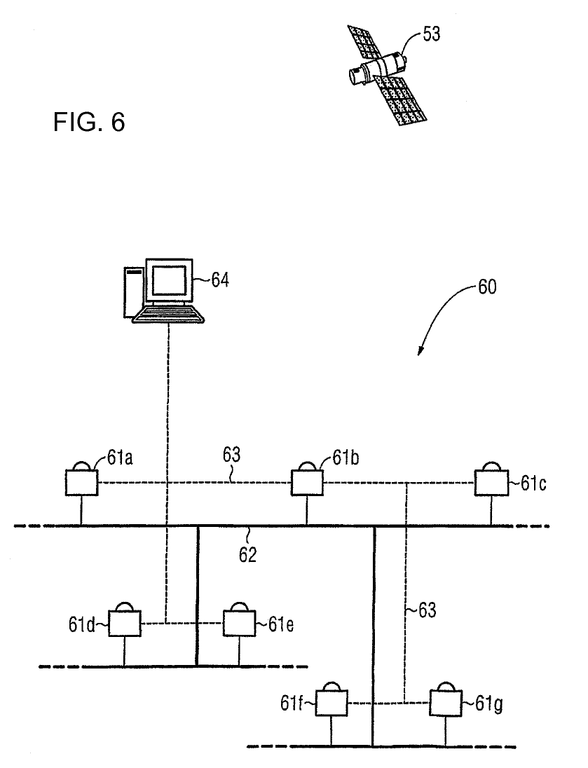

FIG. 6 shows a power quality system which comprises a plurality of electrical power quality field devices.

FIG. 1 shows, very highly schematically, an electrical power quality field device 10. The power quality field device 10 has a measurement device 11 with measurement inputs 12a, 12b and 12c for recording measured values. On the output side, the measurement device 11 in the electrical power quality field device 10 is connected to a control device 13 which is itself connected on the output side to a non-volatile data memory 14. In this context, the expression a non-volatile data memory is intended to mean a data memory which, in contrast for example to a volatile data memory, is suitable for long-term storage of data. This may be a so-called permanent data memory which ensures that data is stored permanently without any external power supply, for example a flash memory or a hard disk. However, for the purposes of the invention, a non-volatile data memory should also be understood as meaning a volatile data memory which is supplied with electrical power via an external power source, in such a way that data is stored permanently at least until the power-buffered volatile data memory is called.

The control device 13 for the power quality field device 10 is also connected to a communication device 15 which, via a communication output 17, sets up a data link between the power quality field device 10 and further devices. Although the communication output is indicated in FIG. 1 as a cable-based data link path, a wire-free data link may also be provided instead of this, for example by radio or infrared, via which data can be sent to an appropriately designed receiving device. Furthermore, the communication device 15 may also be a device by means of which an external data memory can be connected to the power quality field device 10, for example a USB interface or a drive for optical or magnetic data storage media.

The control device 13 is also connected to a timer 18, for example a crystal-controlled internal device clock, which provides the control device with a time pulse by means of which the respective measurement time of the individual measured values recorded by the measurement device 11 can be defined.

The power quality field device 10 represents a field device for monitoring the electrical power quality of components in an electrical power supply system, for example a section of an electrical power transmission line, a busbar or a transformer.

Normally, conventional power quality field devices record measured values of power quality characteristic variables at the individual components and store these continuously in a non-volatile data memory in the conventional electrical power quality field device. Since the non-volatile data memory is designed to store a limited amount of measured values, the measured values stored in it must be read before the memory capacity of the non-volatile data memory is exceeded. A reading process such as this can be carried out either directly at the power quality field device by transmission of the measured values to a transportable data memory, which is temporarily connected to the electrical power quality field device, for example a floppy disk or a USB stick. Alternatively, the measured values can also be transmitted from the electrical power quality field device via a data transmission path, which may be either cable-based or wire-free, to another data processing facility, for example a central evaluation computer.

Since the measured values which are of particular interest for evaluation of the behavior of power quality characteristic variables are those with which an infringement of predetermined threshold values has occurred, in the case of the power quality field device 10 illustrated in FIG. 1, the method as described in the following text with reference to FIG. 2 is carried out in order to monitor the electrical power quality of an electrical power supply system.

In a first step 21, illustrated in FIG. 2, a first measured value M₁ of a first power quality characteristic variable is detected at a measurement input, for example the measurement input 12a, of the electrical power quality field device 10 by means of the measurement device 11. By way of example, the first power quality characteristic variable may be a voltage which is detected on a section of an electrical power supply system. In a second step 22, which follows this, the measurement input 12a of the measurement device 11 is once again used to detect a second measured value M₂ of the first power quality characteristic variable, at a time immediately following the first measured value M. These two detected measured values M₁ and M₂ are transferred to the control device 13 of the electrical power quality field device 10.

According to a following step 23, the control device 13 checks whether the first measured value M₁ recorded in step 21 is below a predetermined threshold value S (M₁<S). If this is the case, then, in a further step 24, the second measured value M₂ recorded in step 22 is then checked to determine whether it is above the predetermined threshold value S (M₂>S). If this is also the case, the control device 13 for the power quality field device 10 produces an event signal ES in a final step 25.

If it is found during the check in step 23 that the first measured value M₁ is not below the predetermined threshold value S, that is to say the first measured value M₁ is in consequence above the predetermined threshold value, then a check is carried out in a step 26 which now follows this to determine whether the second measured value M₂ is below the predetermined threshold value S (M₂<S). If this is the case, then, according to step 27, an event signal ES is produced by means of the control device 13 for the power quality field device 10.

If it is found in step 24 that the second measured value M₂ is not above the threshold value S (that is to say both measured values M₁ and M₂ are below the threshold value S), then, according to step 28, no event signal ES is produced. The procedure is the same in the situation in which it is found in step 26 that the second measured value M₂ is not below the predetermined threshold value S (that is to say both measured values M₁ and M₂ are above the threshold value S), and no event signal is produced, according to step 29.

After each run through the process, it is started again at step 21, with the previous second measured value M₂ now being treated as the first measured value M₁ and a new measured value M₂ being detected.

In order to cope with the rare situation in which one of the measured values or even both is or are precisely equal to the threshold value S, a test based on a greater than or equal to/less than or equal to condition (for example M₁≦S) can be carried out instead of the greater than/less than condition (for example M₁S) in steps 23, 24 and 26.

The event signal ES which is produced by the control device when the measured values M₁ and M₂ infringe the threshold value can be used, for example, to cause a visual indicating device 19 of the power quality field device 10 to emit a visual signal which indicates the threshold value infringement to the operator of the electrical power supply system. In the simplest case, a lamp or a light-emitting diode may be used as the visual indicating apparatus, although it is also possible to use a screen such as a display (for example an LCD), by means of which it is possible to display even further information (for example the time of the threshold value infringement, identification of the threshold value) relating to the threshold value infringement.

However, the event signal ES can also be used to cause the control device to produce a data message which contains at least an identification of the threshold value which has been overshot. In addition, the data message may include further details, for example relating to an identification of the power quality field device 10 (for example a unique serial number), the time of the threshold value infringement (one or both of the measurement times at which the measured values M₁ and M₂ were detected), the direction of the threshold value infringement, that is to say whether the threshold value was overshot or undershot, or the individual measured values M₁ and/or M₂ themselves or itself. The data message produced by the control device 13 may also include a selection of some of said details.

The data message can either be transmitted via the communication device 15 for example to a superordinate data processing facility, or can be stored in the non-volatile data memory 14 in the power quality field device in order to be read from there at a later time.

Finally, the event signal ES can also be used to cause the first measured value M₁ and/or the second measured value M₂ to be stored in the non-volatile data memory in the power quality field device.

Furthermore, the event signal ES can also initiate a plurality of the abovementioned actions in combination, that is to say for example the production of a data message and the indication of a visual signal directly on the power quality field device.

In summary, it can therefore be stated that, when using the method as shown in FIG. 2, an event signal is only ever produced by the control device 13 for the power quality field device 10 when a threshold value infringement has actually occurred. The control device 13 for the electrical power quality field device 10 identifies an infringement such as this when and only when one of the two measured values is below the predetermined threshold value and one of the two measured values is above the predetermined threshold value. In consequence, no continuous measured value profiles are stored in the electrical power quality field device. Even if the event signal ES is used to initiate storage of the measured values M₁ and M₂ in the non-volatile data memory 14 in the power quality field device, this saves a considerable amount of memory space in comparison to continuous measured value storage since data is stored in any case only as a function of events. This effectively results in fewer measured values being stored in the non-volatile data memory 14 in the electrical power quality field device 10. The measured values stored in the non-volatile data memory 14 therefore need be called up from the power quality field device 10 only comparatively rarely, as well.

In addition to the first power quality characteristic variable, for example a voltage, further power quality characteristic variables, such as an electrical power and a frequency, can also be recorded at further measurement inputs 12b and 12c of the measurement device 11 of the electrical power quality field device 10 and these are monitored using the method illustrated in FIG. 2 for threshold value infringements of further threshold values which are each associated with the individual further power quality characteristic variables, and lead to the production of an event signal ES only if a threshold value is overshot. For this purpose, measurement sensors may be provided, connected upstream of the individual measurement inputs 12a to 12c, in order to measure the respective measurement variable. However, it is also possible to carry out measured value preprocessing within the power quality field device 10, for example using a measured current and voltage profile to determine further power quality characteristic variables, such as power and frequency, and to transfer these to the measured value detection device 11 in the electrical power quality field device 10.

The power quality field device 10 may also be a combined power quality field device and protective device. Electrical protective devices monitor components of an electrical power supply system for compliance with predetermined operating states, for example by measuring current and voltage profiles on the respective component and using so-called protective algorithms to check whether the component is in a permissible operating range or whether a fault, for example a short, has occurred. In the event of a fault, an electrical protective device disconnects the component in the electrical power supply system from that system by opening circuit breakers, thus preventing propagation of the fault to the rest of the electrical power supply system. The integration of functions of an electrical power quality field device and of a protective device in a single field device makes it possible to avoid generally costly provision of separate protective and power quality field devices.

The method described in FIG. 2 will be explained further in the following text with reference to measured value profiles illustrated in FIGS. 3 and 4.

In this context, and by way of example, FIG. 3 shows the time profile of voltage measured values V₁ to V₁₂ in the form of a staircase curve on a voltage/time graph.

The illustration in the form of a staircase curve has been chosen because instantaneous values of a power quality characteristic variable are normally not evaluated in power quality field devices, but mean values of this power quality characteristic variable are evaluated, since instantaneous values may be subject to random fluctuations and brief peaks or extreme values may therefore occur. The averaging time period is normally variable and extends, for example, from a few milliseconds up to one or even more minutes or hours. For the purposes of FIGS. 3 and 4, the expression a measured value should therefore be understood as meaning the result of an averaging process over the appropriate averaging time period, for example 10 minutes. As an alternative to this, however, it is just as possible not to carry out any averaging process and to record instantaneous measured values of the power quality characteristic variable at successive measurement times, and to carry out the method described in FIG. 2 using these instantaneous measured values.

The graph in FIG. 3 furthermore shows a first threshold value S₁ and a second threshold value S₂ in the form of lines which are illustrated in dashed form and run parallel to the time axis. This is because the standards for power quality characteristic variables normally stipulate a range within which the power quality characteristic variable must lie in order to ensure adequate quality of the electrical power supply. Any departure from this range, that is to say undershooting of the lower threshold value S₁ or overshooting of the upper threshold value S₂, means that the quality of the electrical power supply cannot be regarded as adequate.

If one considers the measured value profile illustrated in FIG. 3, then it can be seen that both the first and the second voltage measured values V₁ and V₂ are above the lower threshold value S₁ and are below the upper threshold value S₂. The control device 13 (see FIG. 1) carries out the method described in FIG. 2 on these two voltage measured values and finds that no overshooting of one of the threshold values S₁ or S₂ occurred at the time t₁ between the measured values V₁ and V₂. No event signal ES is therefore produced in this method run.

In this situation, the voltage measured value V₁ can be completely deleted, while the voltage measured value V₂ must still be retained for a further run of the method described in FIG. 2. This is because the control device 13 for the electrical power quality field device 10 now carries out the method illustrated in FIG. 2 for the voltage measured values V₂ and V₃. In this case, the control device 13 finds that the voltage measured value V₂ is below the upper threshold value S₂, and that the voltage measured value V₃ is above the upper threshold value S₂. In other words, the upper threshold value S₂ has been overshot between the voltage measured value V₂ and the voltage measured value V₃. In consequence, the control device 13 for the power quality field device 10 produces an event signal ES. By way of example, the presence of the event signal ES can cause the control device to produce a data message which indicates the threshold value infringement, and to transmit this data message to a superordinate data processing facility. Furthermore, the second voltage measured value V₂ and/or the third voltage measured value V₃ (possibly with associated measurement times) can be stored in the non-volatile data memory 14 in the electrical power quality field device 10.

In further runs of the method described in FIG. 2, for the voltage measured values V₃ to V₇, the control device 13 for the electrical power quality field device does not find any further threshold value overshoots since all the voltage measured values V₃ to V₇ are above the upper threshold value S₂. In consequence, no further event signal ES is produced in these runs of the method.

Only when the voltage measured values V₇ and V₈ are analyzed does the control device 13 find a further threshold value overshoot, to be precise with the voltage profile reentering the permissible range. In this case, an event signal is produced again, and can initiate various actions, as explained above.

In a corresponding manner, the control device 13 for the electrical power quality field device 10 finds an infringement of the lower threshold value S₁ between the voltage measured values V₉ and V₁₀, as well as between the voltage measured values V₁₀ and V₁₁, as a result of which event signals are also produced in this case.

If one looks at the measured value profile illustrated in FIG. 3, it can be seen that twelve individual voltage measured values (possibly with their respective measurement times) would be stored for subsequent evaluation in the case of continuous measured value storage. When using the method described in FIG. 2, only four event signals are produced and, for example, initiate the generation of four data messages. Bearing in mind the fact that, in the case of actual measured value profiles, infringement of a threshold value occurs considerably more rarely than in the case of the fictional measured value profile illustrated in FIG. 3, this results in a considerable reduction in the amount of data stored even if the event signal ES were to initiate storage of the respective voltage measured values in the non-volatile data memory 14.

The graph illustrated in FIG. 4 shows a profile of voltage measured values V₁ to V₁₂ which in principle is similar to that in FIG. 3. Just one further threshold value S₃ has been provided in FIG. 4, with respect to which the position of the individual measured values is checked by the control device 13 for the electrical power quality field device 10. Increasing the number of threshold values in this way makes it possible either to match the evaluation of the recorded power quality characteristic variables to a predetermined standard in which more than two threshold values are stipulated, or to increase the resolution of the event signals ES that are produced since, in consequence, an event signal ES is produced more frequently, but also more specifically. Thus, when a further threshold value is introduced in FIG. 4, six event signals ES are now produced instead of four event signals ES (in the case of FIG. 3). This occurs whenever at least one of the threshold values S₁ to S₃ is overshot between two successive measured values.

FIG. 5 shows a further exemplary embodiment of an electrical power quality field device. The electrical power quality field device 50 shown in FIG. 5 is designed in a similar manner to the electrical power quality field device 10 shown in FIG. 1, so that matching components are identified by the same reference symbols. The embodiment of the electrical power quality field device 50 shown in FIG. 5 differs from the power quality field device 10 shown in FIG. 1 only in the nature of the timer by means of which the respective measurement times of the individual measured values are defined. For example, the timer 52, as shown in FIG. 5, of the electrical power quality field device 50 has a receiving device 51 by means of which an external time clock can be received. The timer 52 for the control device 13 for the electrical power quality field device 50 uses the external time clock received via the receiving device 51 to produce a time pulse, which can be used to accurately determine the measurement time of the respective measured value with respect to the external time clock.

As shown in FIG. 5, the receiving device 51 of the timer 52 may, for example, be a GPS (Global Positioning System) receiver, which receives a time clock transmitted from GPS satellites 53 which are installed in orbit. The time clock which is transmitted by the GPS satellites 53 is a high-precision time clock with a frequency of one pulse per second. The control device 13 for the electrical power quality field device 50 can use this accurate time clock to associate a respective measurement time with the individual measured values, with an accuracy, for example, in the microsecond range. Instead of a GPS receiver, which receives the signal from GPS satellites, it is also possible to provide any other receiver which is suitable for receiving a signal with a time clock produced outside the power quality field device 50. Finally, FIG. 6 shows a system comprising a plurality of power quality field devices 61a to 61g, which are arranged on a section of an electrical power supply system 62, which is illustrated only schematically. The electrical power quality field devices 61a to 61g have receiving devices, corresponding to the illustration in FIG. 5, for receiving an external time clock, for example a GPS signal from the GPS satellites 53. This makes it possible to ensure that all the timers in the electrical power quality field devices 61a to 61g run precisely synchronized and thus that absolute measurement times can be associated with the measured values detected by the power quality field devices 61a to 61g, which measurement times are also valid in the other power quality field devices 61b to 61g and can therefore be compared with one another. In other words, this makes it possible to ensure that a measured value which has been recorded in the power quality field device 61b and which the control device for the power quality field device 61b has associated with the measurement time t₁ is recorded at the same time as a further measured value, which is detected in the power quality field device 61f and was likewise associated with the measurement time t₁ by the control device for the power quality field device 61f. If no external time clock were used for all the power quality field devices 61a to 61g, it would in consequence not be possible to make any precise statement as to whether the measurement times t₁ of the field device 61b and t₁ of the power quality field device 61f actually match, as a result of the lack of synchronization between the timers of the individual power quality field devices 61a to 61g. However, in some cases, it may also be sufficient to provide high-precision internal timers, as in the case of the example shown in FIG. 1, if the requirements for synchronization of the measured values of the individual power quality field devices are not as stringent. A power quality system can then be constructed even without an external time clock and without corresponding receiving devices.

As shown in FIG. 6, the individual power quality field devices 61a to 61f are connected to one another and to an evaluation computer 64 via communication lines, which are illustrated by dotted lines. The contents of the data memories of the respective power quality field devices 61a to 61g can be transmitted to the evaluation computer 64 via these communication lines. For example, the communication network may be an Ethernet network, in which communication takes place in accordance with the IEC61850 industry standard. A statement can therefore be made by the evaluation computer 64 on a system-wide basis for all the power quality field devices 61a to 61g under consideration, as to when and how frequently threshold values have been infringed.

1-22. (canceled)

23. A method for monitoring an electrical power quality in an electrical power supply system, which comprises the steps of:
detecting a first measured value of a first power quality characteristic variable using a measurement device of a power quality field device, which is disposed at a measurement point in the electrical power supply system, at a first measurement time;
detecting a second measured value of the first power quality characteristic variable using the measurement device of the power quality field device at a second measurement time, which directly follows the first measurement time;
comparing the first and second measured values with at least one predetermined threshold value; and
producing an event signal, which indicates infringement of the at least one predetermined threshold value, when and only when one of the first and second measured values is above the at least one predetermined threshold value and one of the first and second measured values is below the at least one predetermined threshold value.

24. The method according to claim 23, which further comprises using the event signal to control an optical signaling device of the power quality field device.

25. The method according to claim 23, wherein the event signal causes a control device for the power quality field device to produce a data message, with the data message including at least one data record which indicates an infringed threshold value.

26. The method according to claim 25, which further comprises forming the data message to include a data record which indicates at least one of the first and second measurement times.

27. The method according to claim 25, which further comprises forming the data message to additionally include information about whether the infringed threshold value has been infringed by one of overshooting it and undershooting it.

28. The method according to claim 25, which further comprises forming the data message to additionally include at least one of the first and second measured values.

29. The method according to claim 25, which further comprises performing at least one of:
storing the data message in a non-volatile data memory in the power quality field device; and
transmitting the data message to a data processing facility which is superordinate to the power quality field device.

30. The method according to claim 23, wherein the event signal causes a control device for the power quality field device to store at least one of the first measured value and the second measured value in a non-volatile data memory in the power quality field device.

31. The method according to claim 30, which further comprises:
storing the first and second measured values in the non-volatile data memory; and
storing at least one of the first and second measurement times in the non-volatile data memory.

32. The method according to claim 23, which further comprises recording, via the power quality field device, a time clock of a device-internal timer and using the time clock to determine a measurement time of a respective measured value.

33. The method according to claim 23, which further comprises recording, via the power quality field device, an external time clock and determining a measurement time of a respective measured value on a basis of the external time clock.

34. The method according to claim 23, wherein in addition to measured values of the first power quality characteristic variable, performing the steps of:
detecting measured values of at least one further power quality characteristic variable; and
producing a further event signal when two measured values, with one following the other directly in time, of the at least one further power quality characteristic variable are located on different sides of at least one further threshold value.

35. The method according to claim 23, wherein the event signal causes a control device to additionally carry out further power quality functions of the power quality field device.

36. A power quality field device, comprising:
a measurement device for detecting measured values; and
a control device connected to said measurement device and configured to compare detected measured values with at least one predetermined threshold value and produce an event signal when, of two measured values which follow one another directly, one is above the at least one predetermined threshold value and one is below the at least one predetermined threshold value.

37. The power quality field device according to claim 36, further comprising an optical signaling device which can be activated when the event signal is present.

38. The power quality field device according to claim 36, further comprising a communication device which, when the event signal is present, sends a data message, which indicates an infringed threshold value, to a data processing facility which is superordinate to the power quality field device.

39. The power quality field device according to claim 36, further comprising a non-volatile data memory in which, when the event signal is present, at least one data record which indicates an infringed threshold value is stored by said control device.

40. The power quality field device according to claim 36, wherein said control device is configured to carry out functions for protection of components of an electrical power supply system.

41. The power quality field device according to claim 36, further comprising a device-internal timer for producing a time clock, and said control device determines a respective measurement time of individually detected measured values on a basis of said time clock.

42. The power quality field device according to claim 36, further comprising a receiving device for receiving an external time clock, and said control device determines a respective measurement time of an individually detected measured values on a basis of a received external time clock.

43. The power quality field device according to claim 42, wherein said receiving device is a GPS receiver.

44. A power quality system, comprising:
a plurality of power quality field devices each containing:
a measurement device for detecting measured values; and
a control device connected to said measurement device and configured to compare detected measured values with at least one predetermined threshold value and produce an event signal when, of two measured values which follow one another directly, one is above the at least one predetermined threshold value and one is below the at least one predetermined threshold value;
a data communication network; and
at least one central data processing facility connected to said power quality field devices via said data communication network.
